(19) United States
(12) Patent Application Publication
(10) Pub. No.: US 2019/0157051 A1
(43) Pub. Date: May 23, 2019

(54) METHOD FOR CLEANING CHAMBER

(71) Applicant: Lam Research Corporation, Fremont, CA (US)

(72) Inventors: Leonid BELAU, Pleasanton, CA (US); Eric HUDSON, Berkeley, CA (US)

(21) Appl. No.: 15/817,740

(22) Filed: Nov. 20, 2017

(51) Int. Cl. H01J 37/32; B08B 7/00; B08B 9/00

(52) U.S. Cl. CPC H01J 37/32862; H01J 37/32724; H01L 21/31116; B08B 7/0035; B08B 9/00; H01J 37/32449

(57) ABSTRACT

A method for removing nitrogen containing residues in a plasma processing chamber is provided. A cleaning gas comprising at least one of CO or CO₂ or both is flowed into the plasma processing chamber. A plasma is generated from the cleaning gas, wherein the plasma removes the nitrogen containing residues. The flow of the cleaning gas is stopped.

### BACKGROUND

### Field

The present disclosure relates to a method of forming semiconductor devices on a semiconductor wafer. More specifically, the disclosure relates to cleaning an etch chamber in the formation of memory.

In forming semiconductor devices, etch layers may be etched to form memory holes or lines. Some semiconductor devices may be formed by etching a stack of bilayers of silicon oxide and silicon nitride (ONON) or silicon oxide and polysilicon (OPOP). Such stacks may be used in memory applications, such as in forming dynamic random access memory (DRAM) and three dimensional “negative and” gates (3D NAND). In the formation of such memory structures, plasma processing chambers may be used to etch such memory structures. Residues are deposited within the plasma processing chambers. The residues may need to be removed from time to time between the processing of each substrate.

### SUMMARY

To achieve the foregoing and in accordance with the purpose of the present disclosure, a method for removing nitrogen containing residues in a plasma processing chamber is provided. A cleaning gas comprising at least one of CO or CO₂ or both is flowed into the plasma processing chamber. A plasma is generated from the cleaning gas, wherein the plasma removes the nitrogen containing residues. The flow of the cleaning gas is then stopped.

These and other features of the present disclosure will be described in more details below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIG. 2 is a schematic view of a etch chamber that may be used in an embodiment.

FIG. 3 is a schematic view of a computer system that may be used in practicing an embodiment.

FIG. 4 is a more detailed flow chart of a step of providing a protected clean.

FIG. 5 is an enlarged schematic view of an ESC, an edge ring, and a cleaning wafer.

FIG. 6 is a more detailed flow chart of a step of providing an exposed clean.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

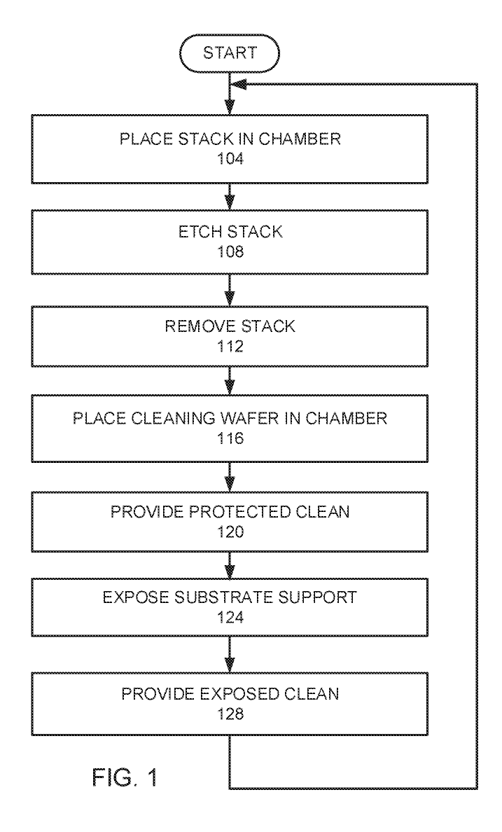

FIG. 1 is a high level flow chart of an embodiment. In this embodiment, a stack is placed in a plasma processing chamber (step 104). The stack is etched (step 108). The stack is removed from the plasma processing chamber (step 112). A cleaning wafer is placed in the plasma processing chamber (step 116). The plasma processing chamber is cleaned using a protected clean (step 120). The protected clean is a process of cleaning the chamber, while the substrate support is protected from the cleaning plasma by a cleaning wafer covering the substrate support. The substrate support is exposed (step 124). The plasma processing chamber is cleaned using an exposed clean (step 128). The exposed clean is a process for cleaning the chamber, while the substrate support is exposed to the cleaning plasma. The process is repeated by going to step 104 and placing another stack in the plasma processing chamber.

### Example

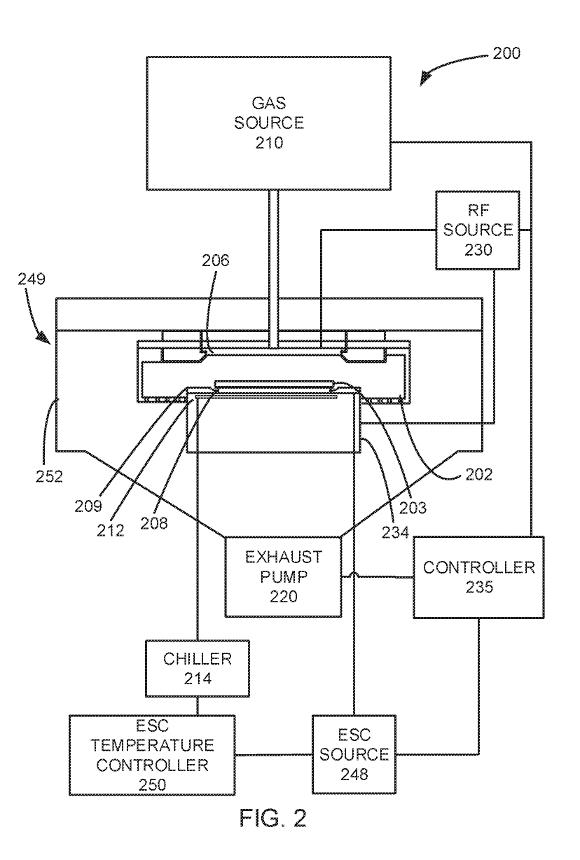

In an exemplary embodiment, a stack is placed in an etch chamber (step 104). FIG. 2 is a schematic view of an etch reactor that may be used in an embodiment. In one or more embodiments, a plasma processing chamber 200 comprises a gas distribution plate 206 providing a gas inlet and an electrostatic chuck (ESC) 208, within an etch chamber 249, enclosed by a chamber wall 252. Within the etch chamber 249, a stack 203 is positioned over the ESC 208, which is a substrate support. An edge ring 209 surrounds the ESC 208. An ESC source 248 may provide a bias to the ESC 208. A gas source 210 is connected to the etch chamber 249 through the gas distribution plate 206. An ESC temperature controller 250 is connected to a chiller 214. In this embodiment, the chiller 214 provides a coolant to channels 212 in or near the ESC 208. A radio frequency (RF) source 230 provides RF power to a lower electrode and/or an upper electrode, which in this embodiment are the ESC 208 and the gas distribution plate 206. In an exemplary embodiment, 400 kHz, 60 MHz, and optionally 2 MHz, 27 MHz power sources make up the RF source 230 and the ESC source 248. In this embodiment, the upper electrode is grounded. In this embodiment, one generator is provided for each frequency. In other embodiments, the generators may be in separate RF sources, or separate RF generators may be connected to different electrodes. For example, the upper electrode may have inner and outer electrodes connected to different RF sources. Other arrangements of RF sources and electrodes may be used in other embodiments. A controller 235 is controllably connected to the RF source 230, the ESC source 248, an exhaust pump 220, and the etch gas source 210. An example of such an etch chamber is the Exelan Flex™ etch system manufactured by Lam Research Corporation of Fremont, Calif. The process chamber can be a CCP (capacitive coupled plasma) reactor or an ICP (inductive coupled plasma) reactor.

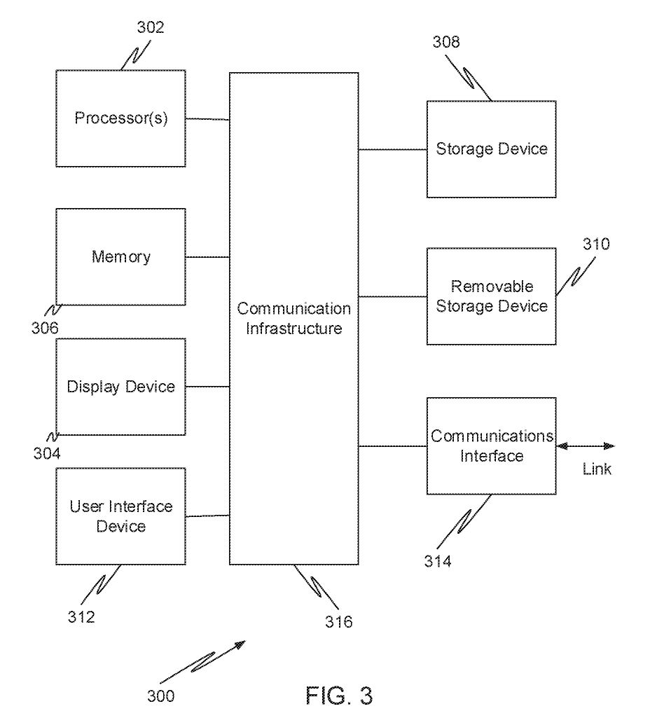

FIG. 3 is a high level block diagram showing a computer system 300, which is suitable for implementing a controller 235 used in embodiments. The computer system may have many physical forms ranging from an integrated circuit, a printed circuit board, and a small handheld device up to a huge super computer. The computer system 300 includes one or more processors 302, and further can include an electronic display device 304 (for displaying graphics, text, and other data), a main memory 306 (e.g., random access memory (RAM)), storage device 308 (e.g., hard disk drive), removable storage device 310 (e.g., optical disk drive), user interface devices 312 (e.g., keyboards, touch screens, keypads, mice or other pointing devices, etc.), and a communication interface 314 (e.g., wireless network interface). The communication interface 314 allows software and data to be transferred between the computer system 300 and external devices via a link. The system may also include a communications infrastructure 316 (e.g., a communications bus, cross-over bar, or network) to which the aforementioned devices/modules are connected.

Information transferred via communications interface 314 may be in the form of signals such as electronic, electromagnetic, optical, or other signals capable of being received by communications interface 314, via a communication link that carries signals and may be implemented using wire or cable, fiber optics, a phone line, a cellular phone link, a radio frequency link, and/or other communication channels. With such a communications interface, it is contemplated that the one or more processors 302 might receive information from a network, or might output information to the network in the course of performing the above-described method steps. Furthermore, method embodiments may execute solely upon the processors or may execute over a network such as the Internet, in conjunction with remote processors that share a portion of the processing.

The term “non-transient computer readable medium” is used generally to refer to media such as main memory, secondary memory, removable storage, and storage devices, such as hard disks, flash memory, disk drive memory, CD-ROM and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

After the stack 203 has been placed into the plasma processing chamber 200, the stack 203 is etched (step 108). In this embodiment, the stack 203 is made of silicon oxide and polysilicon bilayers (OPOP), which is etched to form channel holes for three dimensional memory devices. In this embodiment, the etching of the stack 203 uses a nitrogen containing process gas, which causes nitrogen containing residues, such as ammonium salts, to be deposited on sides and other inner surfaces of the plasma processing chamber 200. Such ammonium salts, such as ammonium fluoride, are difficult to remove. After the etching operation is completed, the stack 203 is removed from the plasma processing chamber 200 (step 112).

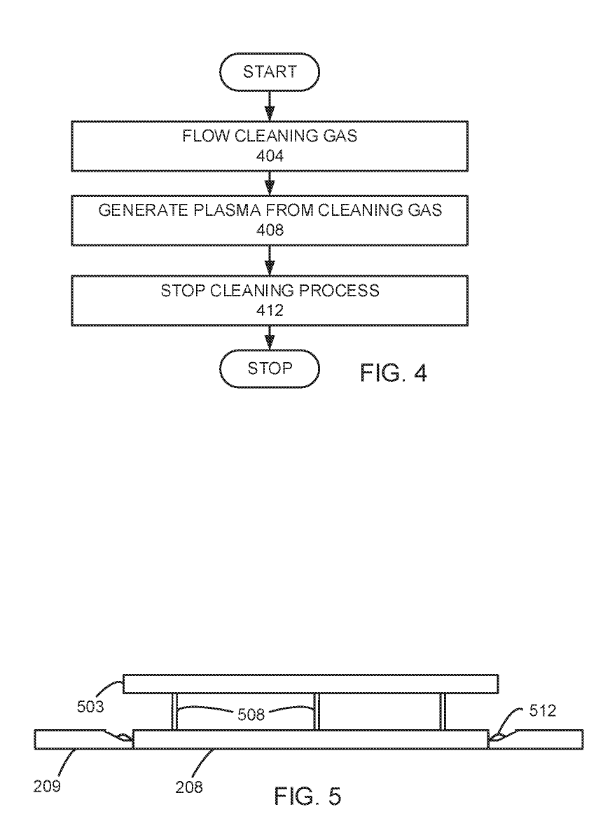

If the nitrogen containing residues are not cleaned from the inner surfaces of the plasma processing chamber 200, the nitrogen containing residues may contaminate the next stack to be etched. Therefore, before the next stack is placed in the plasma processing chamber 200 for etching, the plasma processing chamber 200 is cleaned. In this embodiment, the cleaning of the plasma processing chamber 200 includes placing a cleaning wafer in the plasma processing chamber 200 (step 116). The cleaning wafer is a blank silicon wafer, which is mounted on the ESC 208. The plasma processing chamber 200 is cleaned using a protected clean (step 120). FIG. 4 is a more detailed flow chart of the step of providing a protected clean (step 120). A cleaning gas is flowed into the plasma processing chamber 200 (step 404). In this embodiment, the cleaning gas comprises about 500 sccm to about 3000 sccm of O₂, about 0 sccm to about 100 sccm of NF₃, and about 10 sccm to about 1000 sccm of CO₂. A plasma is generated from the cleaning gas (step 408). In this embodiment, this may be accomplished by providing an excitation RF signal with a frequency of 60 MHz at about 200 to 8000 watts. In this embodiment, a bias with a magnitude of about 0 volts to 1000 volts is provided by having an RF signal with a frequency of 400 kHz at about 0 kW to 2 kW. The protected clean process is then stopped (step 412). In this embodiment, the clean process is stopped after 30 seconds. In various embodiments, the length of the clean process would be dependent on the etch process and duration, type of wafer etched, reactor design and other factors.

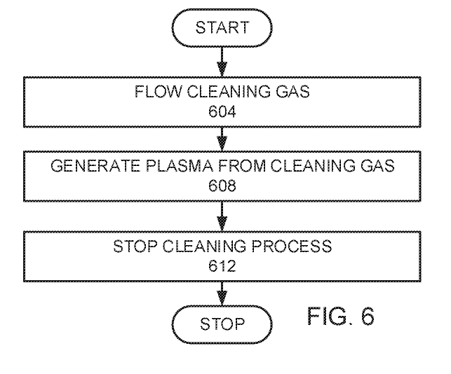

The substrate support is exposed (step 124). In this embodiment, the cleaning wafer is raised above the substrate support. FIG. 5 is an enlarged schematic view of the ESC 208, edge ring 209, and a cleaning wafer 503. The cleaning wafer 503 has been lifted from the ESC 208 by lifting pins 508, so that the top surface of the ESC 208 is exposed. Residue 512 on the edge ring 209 remains after the protected clean (step 120) because the cleaning wafer 503 prevents cleaning plasma from sufficiently cleaning the residue 512. The plasma processing chamber is then cleaned using an exposed clean (step 128). FIG. 6 is a more detailed flow chart of the step of providing an exposed clean (step 128). A cleaning gas is flowed into the plasma processing chamber (step 604). In this embodiment, the cleaning gas comprises about 500 sccm to about 3000 sccm of O₂, about 0 sccm to about 100 sccm of NF₃, and about 10 sccm to about 1000 sccm of CO₂. A plasma is generated from the cleaning gas (step 608). In this embodiment, this may be accomplished by providing an excitation RF signal with a frequency of 60 MHz at about 200 to 1000 watts. In this embodiment, a bias with a magnitude of about 0 volts to 100 volts is provided by having an RF signal with a frequency of 400 kHz at about 0 kW to 1 kW. The exposed clean process is then stopped (step 612). In this embodiment, the clean process is stopped after 30 seconds. In various embodiments, the length of the clean process would be dependent on the etch process and duration, type of wafer etched, reactor design and other factors. The exposed clean removes the residue 512, since the raised cleaning wafer 503 allows plasma to reach and react with the residue 512.

In this embodiment, the ESC 208 is cooled and maintained at a temperature of less than −20° C. The removal of nitrogen containing residues would be more difficult for conventional cleaning processes at such temperatures. It has been unexpectedly found that the addition of CO₂ in the cleaning gas improves the cleaning of nitrogen containing residues, where even at temperatures below −20° C., nitrogen containing residues are removed. In some embodiments, the ESC 208 is cooled to a temperature below −60° C. Other embodiments may provide the cleaning at other temperatures, since it is believed that the addition of CO₂ to the cleaning gas improves the cleaning of nitrogen containing residues at other temperatures.

In addition, it has been unexpectedly found that the addition of CO₂ to the cleaning gas decreases the amount of time needed for cleaning. It has been found that a cleaning process without CO₂ would take about eight (8) minutes compared to the same cleaning process with CO₂, which was found to take about one (1) minute. This time saving is significant which, in turn, improves productivity and throughput. For example, in the etching of memory devices, a cleaning is provided after a wafer is processed, the reduction of cleaning time significantly increases throughput speed, especially when large number of wafers are processed. It has also been found that a cleaning gas of the combination of CO₂, O₂, and a fluorine containing component provides improved cleaning over a cleaning gas with only two of the three components. In addition, various embodiments provide improved cleaning by removing more residues. Such improved cleaning reduces defects caused by remaining residue. In addition, the prior art would require frequent wet clean processes to remove residue that was not removed by the prior art dry clean process. The dry clean process of the embodiments described herein removes a relatively larger amount of residue, which would result in less frequent wet cleaning or even the elimination of wet cleaning.

In some embodiments, the cleaning gas may comprise CO in place of or in addition to CO₂. Generally, the cleaning gas comprises at least one of CO and/or CO₂. More preferably, the cleaning gas comprises at least one of CO and/or CO₂ and a fluorine containing component. More preferably, the cleaning gas comprises at least one of CO and/or CO₂, O₂, and a fluorine containing component. In some embodiments, the fluorine containing component is at least one of NF₃, CF₄, C₂F6, or SF₆.

In the above embodiment, the plasma provided during the protected clean has an ion energy that is greater than the ion energy of the plasma during the exposed clean. This may be accomplished by providing a higher bias during the protected clean compared to the bias during the exposed clean. The exposed clean provides a lower ion energy in order to protect the exposed ESC surface from damage. In various embodiments, the cleaning gas provided during the protected clean has a higher concentration of fluorine containing component than the cleaning gas provided during the exposed clean.

In other embodiments, the two step clean process with a protected clean step and an exposed clean step may be replaced with a single clean process. For example, an embodiment may provide only a protected clean. In another embodiment, a cleaning wafer is not used, so that the exposed clean is a waferless cleaning process.

In other embodiments, other stacks may be etched. Generally, such stacks may be one or more layers of a silicon containing material. For example, in another embodiment ONON is etched. In some embodiments, the stacks are used in the manufacturing of 3D memory.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

1. A method for removing nitrogen containing residues in a plasma processing chamber, wherein the plasma processing chamber comprises a substrate support for supporting a substrate within the plasma processing chamber, comprising:
flowing a cleaning gas comprising at least one of CO or CO₂ or both into the plasma processing chamber;
generating a plasma from the cleaning gas, wherein the plasma removes the nitrogen containing residues;
cooling the substrate support to a temperature below −20° C. while generating a plasma from the cleaning gas; and
stopping the flow of the cleaning gas.

2. The method, as recited in claim 1, wherein the cleaning gas further comprises O₂.

3. The method, as recited in claim 2, wherein the cleaning gas further comprises a fluorine containing component.

4. The method, as recited in claim 1, wherein the cleaning gas further comprises a fluorine containing component.

5. The method, as recited in claim 1, wherein the cleaning gas further comprises at least one of NF₃, CF₄, C₂F₆, or SF₆.

6. The method, as recited in claim 1, wherein the cleaning gas further comprises O₂ and at least one of NF₃, CF₄, C₂F6, or SF₆.

7. The method, as recited in claim 1, wherein the plasma processing chamber comprises a substrate support for supporting a substrate within the plasma processing chamber, wherein the method further comprises uncovering the substrate support before flowing the cleaning gas, wherein the substrate support is exposed to the plasma generated from the cleaning gas.

8. The method, as recited in claim 1, the nitrogen containing residues are generated from an etching process using a nitrogen containing process gas.

9. (canceled)

10. A method for removing nitrogen containing residues in a plasma processing chamber, wherein the plasma processing chamber comprises a substrate support for supporting a substrate within the plasma processing chamber, comprising:
flowing a cleaning gas comprising at least one of CO or CO₂ or both into the plasma processing chamber;
generating a plasma from the cleaning gas, wherein the plasma removes the nitrogen containing residues, wherein the generating the plasma comprises:
generating the plasma while the substrate support is covered, the plasma having a first ion energy; and
generating the plasma while the substrate support is uncovered to expose the substrate support to the plasma, the plasma having a second ion energy which is lower than the first ion energy; and
stopping the flow of the cleaning gas.

11. The method, as recited in claim 10, wherein the flowing the cleaning gas comprises:
flowing the cleaning gas with a first concentration of fluorine while the substrate support is covered; and
flowing the cleaning gas with a second concentration of fluorine while the substrate support is uncovered;
wherein the first concentration is higher than the second concentration.

12. A method for removing nitrogen containing residues in a plasma processing chamber, wherein the plasma processing chamber comprises a substrate support for supporting a substrate within the plasma processing chamber, comprising:
flowing a cleaning gas comprising at least one of CO or CO₂ or both into the plasma processing chamber;
generating a plasma from the cleaning gas, wherein the plasma removes the nitrogen containing residues;
stopping the flow of the cleaning gas;
covering the substrate support, wherein the cleaning gas has a first concentration of fluorine, while the substrate support is covered; and
uncovering the substrate support to expose the substrate support to the plasma, wherein the cleaning gas, while the substrate support is uncovered, has a second concentration of fluorine which is lower than the first concentration.

13. The method, as recited in claim 1, wherein the nitrogen containing residues are ammonium salts.

14. The method, as recited in claim 1, wherein the nitrogen containing residues are residues from a process of etching a silicon containing stack.

15. The method, as recited in claim 14, wherein the silicon containing stack comprises a stack of a plurality of silicon oxide and silicon nitride bilayers or a stack of a plurality of silicon oxide and polysilicon bilayers.

16. The method, as recited in claim 1, wherein the plasma processing chamber comprises a substrate support for supporting a substrate within the plasma processing chamber, wherein the method further comprises cooling the substrate support to a temperature below −60° C.

17. The method, as recited in claim 1, wherein the cleaning gas comprises CO₂.

18. The method, as recited in claim 17, wherein the cleaning gas provides a flow of at least about 10 sccm of CO₂.
